(19) United States
(12) Patent Application Publication
(10) Pub. No.: US 2007/0215323 A1
(43) Pub. Date: Sep. 20, 2007

(54) Heat-dissipating structure

(75) Inventor: I-Che Hsu, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/378,130

(22) Filed: Mar. 17, 2006

(51) Int. Cl. H05K 7/20

(52) U.S. Cl. 165/80.3; 361/704; 361/710

(57) ABSTRACT

A heat-dissipating structure is proposed, which can be attached to a heating member for dissipating heat energy produced by the heating member. The heat-dissipating structure includes a base and a plurality of heat-dissipating fins. The base is attached to the heating member. The plurality of heat-dissipating fins, configured as a netted structure, are fixed on the base. By such arrangement, the heat-dissipating area of the plurality of heat-dissipating fins can be increased to improve the heat-dissipating effect, so as to eliminate the drawback of low heat-dissipation of a prior-art heat sink.

### FIELD OF THE INVENTION

The present invention relates to heat-dissipating structures, and more particularly, to a heat-dissipating structure having a plurality of heat-dissipating fins arranged in a netted structure.

### BACKGROUND OF THE INVENTION

Generally speaking, heat dissipation of a central processing unit (CPU) is achieved by means of conduction via a contacting medium such as a heat sink. After the heat sink absorbs heat energy, it dissipates this heat energy via convection. In the process of convection, the heat-dissipating area of the heat sink is mainly determined by the surface area of heat-dissipating fins. The bigger the surface area is, the better the effect of heat dissipation.

The means of providing adequate heat dissipation generally adopted by manufacturers mainly involves increasing the amount and the dimensions of the heat-dissipating fins. In other words, when the keep-out is determined, the thickness to height ratio of the heat-dissipating fin is emphasized. If the ratio is smaller, a relatively larger number of heat-dissipating fins of the same unit volume can be fabricated. Thus, as the number of the heat-dissipating fins becomes larger, the surface area for dissipating heat energy also becomes larger, so as to improve heat dissipation.

FIG. 1 is a schematic diagram showing a prior-art heat sink 11 fixed on a CPU 13. Referring to FIG. 1, the heat sink 11 comprises a bottom board 111 and a plurality of heat-dissipating fins 113 attached to the bottom board 111. When a fan 15 blows the air through a plurality of channels 1131 formed between the plurality of heat-dissipating fins 113, the heat energy absorbed by the surface of the heat-dissipating fins 113 can be dissipated.

However, the thickness to height ratio of the heat-dissipating fin is constrained by the strength of material. If the thickness is too thin, cracks can form. Furthermore, the heat-dissipating area of the heat sink 11 is the sum of the surface areas of the heat-dissipating fins 113. Thus, the size of the heat-dissipating area will influence the heat dissipation effect of the CPU 13. Therefore, this sort of prior-art heat sink 11 has a lower heat dissipation rate because of a relatively smaller heat dissipation area. Also, the spaces formed between the plurality of heat-dissipating fins 113, referred to as channels 1131, do not provide a high degree of mixing of the air flow, and, therefore, a low heat dissipation effect results. Additionally, as friction is generated when air flows through the channel 1131 formed between the heat-dissipating fins 113, kinetic energy is consumed. The lost kinetic energy is unable to be re-supplied, such that the mean air flow speed through the plurality of heat-dissipating fins 113 is reduced and heat dissipation is adversely affected in a later stage.

What is needed, therefore, is to provide a heat-dissipating structure, which is able to improve heat dissipation efficiency by increasing the degree of mixing of the air flowing through the spaces between the plurality of heat-dissipating fins 113. Also, a better utilization rate within the same heat-dissipating area can be provided if kinetic energy can be re-supplied to improve the mean air flow speed through the plurality of heat-dissipating fins 113 in a later stage.

### SUMMARY OF THE INVENTION

In light of the above prior-art drawbacks, a primary objective of the present invention is to provide a heat-dissipating structure to improve heat dissipation efficiency.

Another objective of the present invention is to provide a heat-dissipating structure in which the heat-dissipating area is increased.

Still another objective of the present invention is to provide a heat-dissipating structure that is able to save materials.

A further objective of the present invention is to provide a heat-dissipating structure that is able to offer a high degree of mixing of the airflow body.

A further objective of the present invention is to provide a heat-dissipating structure, by which kinetic energy can be re-supplied to improve airflow speed in a later stage.

In accordance with the foregoing and other objectives, the present invention proposes a heat-dissipating structure that can be attached to a heating member for dissipating heat energy produced by the heating member. The heat-dissipating structure comprises a base and a plurality of heat-dissipating fins. The base is attached to the heating member, and the plurality of heat-dissipating fins having a netted structure are fixed on the base, which allow the heat-dissipating area of the plurality of heat-dissipating fins to be increased to improve heat dissipation.

The foregoing heat-dissipating structure further comprises a fan that can be formed on one side of the plurality of heat-dissipating fins. The base can be made of a copper material or an aluminum material and is formed with a plurality of fixing grooves which can be U-shaped structures. Also, the heat-dissipating structure further comprises a fixing means that can be attached in the fixing groove of the base for connecting the heat-dissipating fins. The fixing means can be a U-shaped structure corresponding to the shape of the fixing groove of the base. Additionally, the fixing means can be solder paste, soldering tin, or any material high in thermal conductivity. The fixing means can be connected to the heat-dissipating fin by methods including surface mounting, soldering, riveting, snap-fitting or other effective connecting methods. Further, a heat-dissipating fin can be a netted structure formed by a plurality of cross-linked cylinders, or alternatively, can be a netted structure consisting of copper bars or aluminum bars. The plurality of heat-dissipating fins can be arranged in a V-shape, a W-shape, an M-shape or an X-shape. More preferably, the plurality of heat-dissipating fins can be arranged in an XX-shape.

The plurality of heat-dissipating fins of the heat-dissipating structure proposed in the present invention is preferably arranged in an XX-shape. When a fan blows air through the two channels formed at the front side of the heat-dissipating fins arranged in an XX-shape, the air is forced to flow through the netted structure of the heat-dissipating fins, which consists of the plurality of cross-linked cylinders. Thus, the air is concentrated in the middle portion of the heating member, which is the place where the largest amount of heat energy is generated. Also, small eddies are formed when the air flows through spaces formed by the plurality of cylinders, such that the degree of mixing of the air can be improved. Moreover, kinetic energy can be re-supplied to concentrate the air in a position of the heating member where the largest amount of heat energy is generated. Referring to the prior-art, when air flows through the channels formed between the plurality of heat-dissipating fins, friction is generated and kinetic energy is consumed, such that heat-dissipating efficiency decreases. Therefore, the present invention is able to improve the heat-dissipating efficiency of the heating member, compared to the prior art.

Referring to the heat-dissipating structure proposed in the present invention, each heat-dissipating fin is a netted structure formed by a plurality of cross-linked cylinders. The total surface area of the plurality of the cylinders is larger than the total area of two surfaces of the prior-art heat-dissipating fin having a plate structure. Thus, the present invention is able to increase the heat-dissipating area of a heat-dissipating fin, so as to solve a prior-art problem of an insufficient heat-dissipating area.

Accordingly, the heat-dissipating structure proposed in the present invention is able to increase the heat-dissipating area of the heat-dissipating fins and improve heat-dissipating efficiency. Further, the degree of mixing of the airflow body can be increased, such that kinetic energy can be re-supplied.

### BRIEF DESCRIPTION OF THE DRAWINGS

The present invention can be more fully understood by reading the following detailed description of the preferred embodiments, with reference made to the accompanying drawings, wherein:

FIG. 1 is a perspective view of a prior-art heat sink fixed on a central processing unit (CPU);

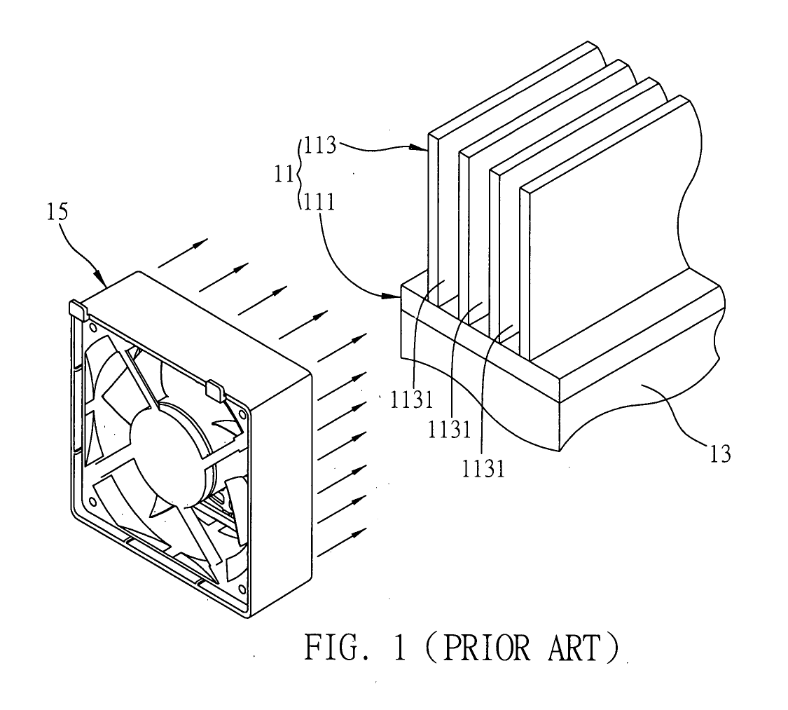

FIG. 2 is a perspective view of a heat-dissipating structure applied to a heating member according to the present invention; and

FIG. 3 is a perspective view of a base of a heat-dissipating structure according to present invention.

### DETAILED DESCRIPTION OF THE EMBODIMENTS

The present invention is described in the following with specific embodiments, and one skilled in the pertinent art can easily understand other advantages and effects of the present invention from the disclosure of the invention. The present invention may also be implemented and applied according to other embodiments, and the details may be modified based on different views and applications without departing from the spirit of the invention. Note that these drawings are simplified schematic diagrams, and thus only constructs relevant to the present invention are illustrated. Also, these constructs are not drawn according to the actual amount, shapes, and dimensions. In application, the amount, shapes, and dimensions are an optional design and the arrangements of the constructs may be very complex in the reality.

The following embodiment serves to provide further description for the present invention with no intent to limit the scope of the invention.

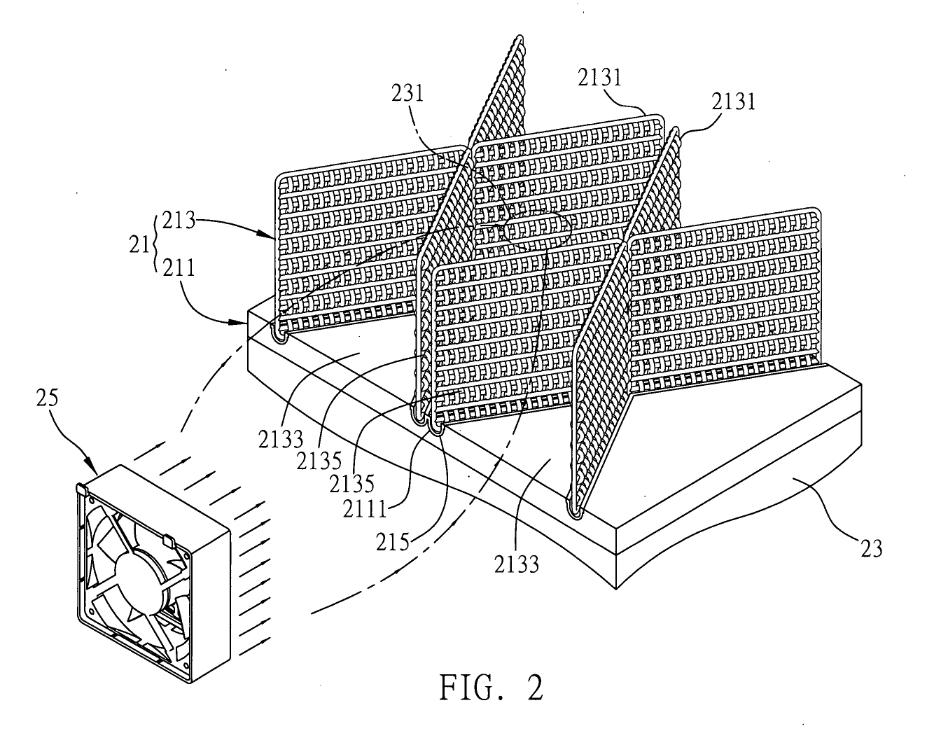

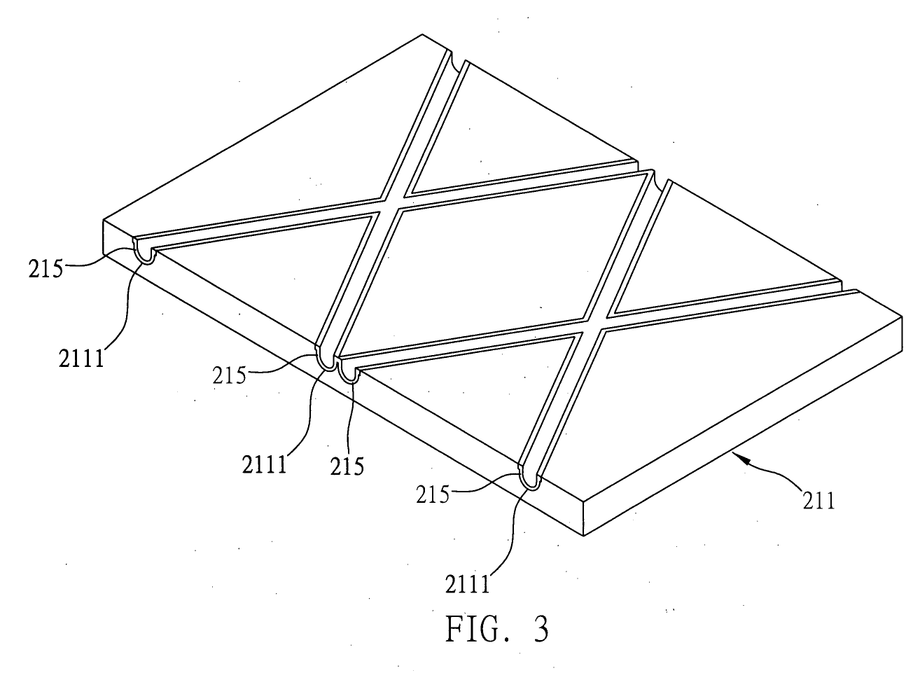

FIG. 2 is a perspective view of a heat-dissipating structure 21 applied to a heating member 23 according to the present invention, and FIG. 3 is a perspective view of a base 211 of the heat-dissipating structure 21 according to present invention. Referring to FIG. 2, the heat-dissipating structure 21 is attached to the heating member 23 for dissipating heat energy produced by the heating member 23. The heat-dissipating structure 21 comprises a base 211 and a plurality of heat-dissipating fins 213. The heating member 23 can be a central processing unit (CPU), a semiconductor package, a chip, other electric/electronic elements, or any device that generates a large amount of heat and requires heat dissipation.

Referring to FIG. 2 and FIG. 3, the heat-dissipating structure 21 further comprises a fan 25 which can be formed on one side of the plurality of heat-dissipating fins 213. The base 211 which can be made of a copper material, an aluminum material or other materials having good thermal conductivity can be attached to the heating member 23. The base 211 is also formed with a plurality of fixing grooves 2111 which can be U-shaped structures. Also, the heat-dissipating structure 21 further comprises a fixing means 215 which can be attached to the base 211 for connecting the heat-dissipating fins 213. The fixing means 215 can be a U-shaped structure corresponding to the shape of the fixing grooves 2111. Additionally, the fixing means 215 can be solder paste, soldering tin, or any material high in thermal conductivity, wherein the fixing means 215 is connected to the heat-dissipating fins 213 by methods including surface mounting, soldering, riveting or snap-fitting.

Referring to FIG. 2, the heat-dissipating fins 213 that are fixed on the base 211 can be netted structures. In the present embodiment, each heat-dissipating fin 213 is preferably a netted structure formed by a plurality of cross-linked cylinders 2131. Note that the shape of the cylinder 2131 of the heat-dissipating fin 213 can be modified. For example, the shape can be rectangular, flat, or oval. Also, a heat-dissipating fin 213 can be made of material such as copper, aluminum, or other materials high in thermal conductivity. Furthermore, the plurality of heat-dissipating fins 213 can be preferably arranged in an XX-shape to improve the heat-dissipating efficiency. Alternatively, the plurality of heat-dissipating fins 213 can also be arranged in a V-shape, a W-shape, an M-shape or an X-shape. Such arrangement can be easily understood by one skilled in the pertinent art and thus will not be further described.

In the present embodiment, the plurality of heat-dissipating fins 213 of the heat-dissipating structure 21 proposed in the present invention is preferably arranged in an XX-shape. When the fan 25 blows the air through the plurality of channels 2133 formed at the front of the heat-dissipating fins 213 arranged in an XX-shape, the air is forced to flow through the netted structure of the heat-dissipating fins 213 consisting of the plurality of cross-linked cylinders 2131 via a plurality of spaces 2135, provided that the spaces 2135 are formed by the cross-linked cylinders 2131. Thus, the air is concentrated at a position 231 (depicted with an oval) near the heating member 23 where the largest amount of heat energy is generated (as shown in FIG. 2). Also, small eddies are formed when the air flows through the plurality of cylinders 2131, such that the degree of mixing of the air flow body can be improved. Moreover, kinetic energy can be re-supplied to concentrate the air in the position 231 near the heating member 23 where the largest amount of heat energy is generated, so as to improve the heat-dissipating efficiency of the heating member 23. Additionally, the plurality of spaces 2135 formed by the plurality of cylinders 2131 result in a reduction of material and weight for the heat-dissipating fins 213.

As the heat-dissipating fin 213 is a netted structure consisting of the plurality of cross-linked cylinders 2131, the surface area of the plurality of cylinders 2131 is greater than the surface area of the prior-art heat-dissipating fin 113 having a plate structure. Therefore, the heat-dissipating area of the heat-dissipating fin 213 can be increased to improve heat-dissipating efficiency.

Accordingly, the heat-dissipating structure 213 proposed in the present invention is able to increase the heat-dissipating area, and save materials. Further, the degree of mixing of the airflow body can be increased, such that kinetic energy can be re-supplied. In conclusion, the present invention is able to improve the overall heat-dissipating efficiency, so as to eliminate various prior-art drawbacks.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A heat-dissipating structure attached to a heating member for dissipating heat energy produced by the heating member, the heat-dissipating structure comprising:
a base attached to the heating member; and
a plurality of heat-dissipating fins having a netted structure and fixed on the base, such that heat-dissipating area of the plurality of heat-dissipating fins is increased to provide an improved heat dissipation effect.

2. The heat-dissipating structure of claim 1, further comprising a fan attached to one side of the plurality of heat-dissipating fins.

3. The heat-dissipating structure of claim 1, wherein the base is made of a material selected from the group consisting of copper and aluminum.

4. The heat-dissipating structure of claim 1, wherein the base comprises a plurality of fixing grooves.

5. The heat-dissipating structure of claim 4, wherein at least one of the plurality of fixing grooves is formed as a U-shaped structure.

6. The heat-dissipating structure of claim 1, further comprising a fixing means attached to the base, being for connected to the plurality heat-dissipating fins.

7. The heat-dissipating structure of claim 6, wherein the fixing means is a U-shaped structure.

8. The heat-dissipating structure of claim 6, wherein the fixing means is one of solder paste and soldering tin.

9. The heat-dissipating structure of claim 6, wherein the connection between the fixing means and the plurality of heat-dissipating fins is formed by on of surface mounting, soldering, riveting and snap-fitting.

10. The heat-dissipating structure of claim 1, wherein each of the plurality of heat-dissipating fins is respectively a netted structure formed by a plurality of cross-linked cylinders.

11. The heat-dissipating structure of claim 1, wherein structure of the plurality of heat-dissipating fins is selected from one of a copper bar and an aluminum bar.

12. The heat-dissipating structure of claim 1, wherein the plurality of heat-dissipating fins are arranged in a shape selected from the group consisting of a V-shape, a W-shape, an M-shape, an X-shape, and an XX-shape.
